(19) United States
(12) Patent Application Publication
(10) Pub. No.: US 2018/0255642 A1
(43) Pub. Date: Sep. 6, 2018

(54) BARRIER LAYER DELAYING OXYGEN DEPLETION IN SEALED GAS-FILLED LED LAMPS

(71) Applicant: PHILIPS LIGHTING HOLDING B.V., EINDHOVEN (NL)

(72) Inventors: Dirk VELDMAN, EINDHOVEN (NL); Wijnand Evert Jacobus VAN KOOTEN, EINDHOVEN (NL); Johannes Gerrit Jan BEIJER, EINDHOVEN (NL); Johan Frans Justin Maria CAERS, EINDHOVEN (NL)

(21) Appl. No.: 15/759,898

(22) PCT Filed: Aug. 29, 2016
(86) PCT No.: PCT/EP2016/070293

§ 371 Date: Mar. 14, 2018

(30) Foreign Application Priority Data
Sep. 15, 2015 (EP) 15185190.4

(51) Int. Cl. H05K 1/18; F21K 9/232; H05K 1/03; F21K 9/64; H05K 1/09; F21V 29/50

(52) U.S. Cl. CPC H05K 1/181; F21K 9/232; H05K 1/032; F21Y 2115/10; H05K 1/09; F21V 29/50; H05K 2201/10106; F21K 9/64

(57) ABSTRACT

The invention provides a lighting unit (10) comprising (a) a lighting device (100), (b) a support (200), and (c) an envelope (300), wherein: —the lighting device (100) is configured to provide lighting device light (101); wherein the lighting device (100) comprises a light source (110); —the support (200) is configured to support the light source (110); wherein the 5 support (200) comprises a laminate of layers, wherein the laminate of layers comprises an electrically conductive first layer, an electrically non-conducive second layer), and a third layer, wherein the first layer comprises copper, wherein the second layer comprises an epoxy-based material, and wherein the third layer comprises an oxygen barrier material; —the envelope (300) is configured to provide a sealed space (310) enclosing the 10 light source (110) and at least part of the support (200); wherein the envelope (300) comprises an envelope part (320) transmissive for the lighting device light (101), and wherein the sealed space (310) comprise a filling gas (330) comprising a thermally conductive gas, wherein the filling gas (330) at least comprises oxygen (O₂).

### FIELD OF THE INVENTION

The invention relates to a lighting unit. The invention also relates to an assembly of a light source and support for use in such lighting unit. The invention also relates to a method for producing such assembly. The invention further relates to a method for producing the lighting unit.

### BACKGROUND OF THE INVENTION

Lighting bulbs with LEDs and a filling gas are known in the art. WO2013154932, for instance, describes that in a sealed environment operating an LED in an oxygen depleted environment may cause degradation of the LED. One result of such degradation is the browning of the silicone that may be used as an encapsulant for the LED chip. According to WO2013154932, it is believed that the browning of the silicone may be caused by a combination of the environment in which the LED is operated (oxygen depleted), contaminants such as organics in the LED assembly or other components in the enclosure, the flux density of the optical energy from the LEDs and/or the thermal energy generated by the LEDs. While, according to WO2013154932, the exact cause of the degradation is not known, WO2013154932 proposes that the adverse effects may be prevented or reversed by lowering or eliminating the contaminants and/or by operating the LED in an oxygen containing environment. An LED that is operated in an oxygen containing environment does not exhibit the degradation, and the degradation of an LED that occurs due to the lack of oxygen may be reversed by operating the LED in an oxygen containing environment. The amount of oxygen used in the enclosure may be related to the presence or absence of the contaminants such that in an environment containing few contaminants less oxygen is required and in an environment containing higher levels of contaminants higher levels of oxygen may be required. In some embodiments of WO2013154932, no oxygen is required such that the gas may contain only highly efficient thermal gas such as H₂ and/or He. In environments having low levels of contaminants the oxygen may comprise approximately 5%, 4% or less by volume of the total gas in the enclosure such as approximately 1%. The oxygen may comprise less than approximately 50% by volume of the total gas in the enclosure. In some embodiments of WO2013154932, the oxygen may comprise less than approximately 40% or less than approximately 25% by volume of the total gas in the enclosure.

### SUMMARY OF THE INVENTION

Hermetically sealed LED bulbs which are filled with helium (and oxygen) for cooling appear to suffer from thermal oxidation when standard single-sided copper (SSC) “copper clad laminates” (CCL) are used as printed circuit board (PCB) material.

For instance, it seems that when all oxygen (O₂) has been consumed, rapid light loss occurs by darkening of the silicone containing the phosphor (above the LED die). Hence relatively high amounts of O₂ need to be supplied to prevent rapid lumen output loss. However, the supply of additional O₂ negatively impacts the thermal resistance (Rth) of the gas-filled lamp.

Hence, it is an aspect of the invention to provide an alternative lighting unit, which preferably further at least partly obviates one or more of above-described drawbacks. Especially, it is an aspect of the invention to provide a lighting unit that has a lifetime of at least 10,000 hours. It is yet a further aspect of the invention to provide a production process for the alternative lighting unit or an essential element thereof.

It was found that some O₂ may be desirable in view of lifetime, but it was also found that the O₂ content could be substantially reduced with respect to commercially available lighting units, which may enclose about 20 vol. % or more O₂.

The inventors surprisingly found that the level of O₂ required to meet lifetime requirements can be reduced by introducing a barrier (e.g. copper) layer to the non-functional side of the CCL. Without the desire to be bound by theory, it seems that thermal oxidation of the epoxy comprising composite material can be delayed and/or reduced. The presently proposed solution may include a more elaborate production process and may be more expensive than state of the art solutions, but surprisingly appears a relevant beneficial factor for the lifetime improvement of the lighting unit. For instance, using a “double sided copper” (DSC) CCL strongly reduces the oxidation rate of the organic composite material (epoxy) in the CCL, enabling longer lifetimes, allowing a lower O₂ content, and thereby improving thermal resistance.

Hence, in a first aspect the invention provides a lighting unit (herein also indicated as “unit” or “lamp”) comprising (a) a lighting device, (b) a support, and (c) an envelope (can also be indicated as “enclosure”), wherein:
the lighting device is configured to provide lighting device light; wherein the lighting device comprises a light source (configured to provide light source light);
the support is configured to support the light source; wherein the support comprises a laminate of layers, wherein the laminate of layers comprises an electrically conductive first layer, an electrically non-conducive second layer, and a third layer, wherein the first layer especially comprises copper, wherein the second layer especially comprises one or more of a phenolic-based material and an epoxy-based material, especially an epoxy-based material, and wherein the third layer especially comprises an oxygen barrier material;
the envelope is configured to provide a sealed space enclosing the light source and at least part of the support; wherein the envelope comprises an envelope part transmissive for the lighting device light, and wherein the sealed space comprise a filling gas comprising a thermally conductive gas, wherein the filling gas at least comprises (in addition to the thermally conductive gas) oxygen (O₂).

It appears that such lighting unit has a longer lifetime with less O₂. With the present invention also the temperature of the light sources may increase less, as the thermally conductive gas may have a better thermal conduction due to the reduced oxygen content. Hence, the total light source power may be reduced, while still having substantially the same output as compared with commercially available other solutions with a higher oxygen content. In this way, the lighting unit may gain efficiency, if desired power, and may also gain lifetime. At least part of such gain may also be exchanged for a cost reduction.

The lighting unit may include more elements than described herein, such as further optics, including optical filters, electronics, ballast, controls, etc. However, such elements are known to a person skilled in the art and do not need further specific attention. Below, the lighting unit is discussed in more detail.

The lighting unit comprises a lighting device, a support, and an envelope.

The lighting device is especially configured to provide lighting device light. The lighting device can be configured to provide white light or to provide colored light. Consequently, the lighting unit light, which is substantially the lighting device light downstream from the transmissive part of the envelope (see below) is white light or colored light. However, as indicated above it is not excluded that further optical elements are used, such as filters. Hence, the light transmissive part may optionally have an optical filter function and/or an optical filter may optionally be configured downstream from the light transmissive part.

The terms “upstream” and “downstream” relate to an arrangement of items or features relative to the propagation of the light from a light generating means (here the especially the light source), wherein relative to a first position within a beam of light from the light generating means, a second position in the beam of light closer to the light generating means is “upstream”, and a third position within the beam of light further away from the light generating means is “downstream”.

Especially however, the lighting unit light may be white light. Hence, in a specific embodiment the lighting unit is configured to provide white light (during operation of the lighting unit). However, especially when a plurality of lighting devices and/or a plurality of light sources (see also below) are applied, the lighting unit may also be configured to provide lighting unit light having a variable color point and/or a variable color temperature. A control unit, optionally integrated in the lighting unit, may be configured to control the color point and/or color temperature. Hence, the term “lighting device” may in embodiments also refer to a plurality of different lighting devices.

The lighting device comprises a light source. In a specific embodiment, the light source comprises a solid state LED light source (such as a LED or laser diode). Especially, the light source comprises a solid state light sources based on one or more of Gallium(III) phosphide (GaP), Aluminum gallium indium phosphide (AlGaInP), Aluminum gallium phosphide (AlGaP), Indium gallium nitride (InGaN)/Gallium(III) nitride (GaN), Indium gallium nitride (InGaN), Silicon carbide (SiC), Boron nitride, Aluminum nitride (AlN), Aluminum gallium nitride (AlGaN), Aluminum gallium indium nitride (AlGaInN), etc. etc. The light source may also comprise an organic LED (OLED).

The light source is configured to provide light source light. The term “light source” may also relate to a plurality of light sources, such as 2-512, such as 2-20 (solid state) LED light sources. Hence, the term LED may also refer to a plurality of LEDs.

In specific embodiments, the lighting device further comprises a light converter configured to convert at least part of the light source light into light converter light, wherein the lighting device light comprises at least part of said light converter light and optionally part of said light source light. As indicated above, in embodiments the lighting unit light may thus comprise at least part of said light converter light and optionally part of said light source light (i.e. unconverted light). In such embodiments, the light source may be configured to provide UV radiation and/or blue light. Optionally, the light source may be configured to provide green or yellow light. Also combinations of different types of light sources may be applied (providing light source light having substantially different dominant wavelengths). The converter element and light source are configured to provide at least light converter light. The light source excites a luminescent material, comprised by the light converter, which converts at least part of the excitation light into luminescence (light converter light). Hence, the light converter, especially the luminescent material comprised by the light converter, is radiationally coupled with the light source.

The term “radiationally coupled” especially means that the light source and the light converter (luminescent material) are associated with each other so that at least part of the radiation emitted by the light source is received by the light converter (luminescent material) (and at least partly converted into luminescence by the light converter (luminescent material)). The lighting device may be configured to provide white lighting device light and/or colored lighting device light.

In embodiments where a plurality of light sources is applied, each single light source may radiationally coupled with a dedicated light converter. In other embodiments the plurality of light sources each address a single “shared” light converter. In yet other embodiments, the plurality of light sources include two or more subsets, with each subset of light sources addressing a dedicated light converter, respectively. Of course, for any of these embodiments the application of a plurality of different lighting devices may also be possible.

With respect to the above indicated light converter, the invention also provides embodiments wherein the light converter comprises a polymeric material and a luminescent material, and wherein the polymeric material especially comprises a polysiloxane material.

Especially, the luminescent material may be embedded in the polymeric material. The term “embedded” may e.g. indicate that the luminescent material is molecularly dispersed, such as in the case of organic luminescent materials. The term “embedded” may also refer to a dispersion of particles in the (solid) polymer. Hence, the polymeric material may be configured as host material. The luminescent material may include an inorganic luminescent material and/or an organic luminescent material. The inorganic luminescent material may include quantum dot particles.

A polysiloxane is a polymer of siloxane groups. The polysiloxane is especially solid at 20° C., and also at maximum operation power. The light converter may reach a temperature in the range of about 100-140° C. at maximum operation power of the lighting unit.

The light source especially comprises a light emissive surface. The converter may in embodiments be configured remote from the light source(s) but may also in embodiments be configured adjacent to the light emissive surface. Especially, in embodiments the light converter is configured in physical contact with the light emissive surface.

Therefore, in embodiments the light source comprises a solid state light source, wherein the light source comprises a light emissive surface, and wherein the light converter is configured in physical contact with the light emissive surface. The converter may e.g. be configured as dome or as layer. For instance, the layer or dome may be configured on the light emissive surface of the light source.

It surprisingly appeared that the combination of the epoxy-based support and the siloxane in the presence of oxygen lead to the decrease in lifetime. Hence, instead of a conventional “single-sided copper” (SSC) “copper clad laminate” (CCL) a modified laminate is applied.

Epoxy laminates are known in the art and can be used as or for printed circuit boards (PCB). Hence, herein epoxy laminates are applied. Single side laminates in general comprise a plurality of non-conductive layers, based on epoxy, and at one side of the stack of non-conductive layer a conductive layer. The terms “epoxy based”, “epoxy” and similar terms refer to a material comprising the cured end product of an epoxy resin. For instance, an epoxy-impregnated woven glass layer (glass cloth) may be used as second layer. Especially, epoxy resins, also known as polyepoxides, are a class of reactive prepolymers and polymers which contain epoxide groups. Epoxy resins may be reacted (cross-linked) either with themselves through catalytic homopolymerisation, or with a wide range of co-reactants including polyfunctional amines, acids (and acid anhydrides), phenols, alcohols and thiols.

In embodiments, the second layer comprises a stack of layers. The epoxy-based material may e.g. be available in the second layer in an amount of 30-70 wt. %. Glass material, like glass fibers or glass fiber cloths, may be available in the second layer in an amount of 30-70 wt. %.

Instead of or in addition to glass material in the second layer, also (cellulosic) paper may be applied.

In addition to or alternative to the epoxy resin, (also) a phenolic resin may herein be applied. Hence, in other embodiments and aspects the support may an epoxy-based and/or phenolic-based support, with the support thus including one or more of an epoxy resin and a phenolic resin. Hence, the second layer may comprise one or more of an epoxy resin and a phenolic resin, and optionally one or more of glass material or paper. Phenol formaldehyde resins (PF), or “phenolic resins”, are synthetic polymers obtained by the reaction of phenol or substituted phenol with formaldehyde. Hence, in embodiments the second layer especially comprises one or more of a phenolic-based material and an epoxy-based material.

Hence, the invention provides an alternative support. The support is configured to support the light source (or the plurality of light sources). Hence, in embodiments the lighting unit comprises a plurality of light sources, and the support is configured to support said plurality of light sources. The term “support” may in embodiments also refer to a plurality of supports. Hence, the lighting unit may in embodiments include a plurality of supports (and thus also a plurality of light sources (in general also a plurality of lighting devices.

Especially, the support comprises a laminate of layers, wherein the laminate of layers comprises an electrically conductive first layer, an electrically non-conducive second layer, and a third layer, wherein the first layer especially comprises copper, wherein the second layer especially comprises an epoxy-based material, and wherein the third layer especially comprises an oxygen barrier material. It appears that the third layer especially has a beneficial effect on the lifetime. The oxygen layer may especially include any layer that prevents oxygen migrating from the envelope to the second layer. It seems that the epoxides oxidize leading to the generation of products that provoke or enhance browning of polymeric material used for their optical properties, such as the polysiloxane.

Instead of or in addition to copper, the first layer may (also) comprise another electrically conductive material, such as e.g. aluminum. Hence, in embodiments and aspects the electrically conductive first layer may comprise one or more of copper and aluminum. However, other electrically conductive materials may also be applied. The first layer is especially textured, with an electrically conductive layer comprising electrically conductive tracks and electrically non-conductive parts between the tracks (e.g. where the electrically conductive material is not provided or has been removed, such as by etching).

In specific embodiments, the light source is configured to provide light source light, and the lighting device further comprises a light converter configured to convert at least part of the light source light into light converter light, wherein the lighting device light comprises at least part of said light converter light and optionally part of said light source light, wherein the light converter comprises a polymeric material and a luminescent material, wherein the polymeric material comprises a polysiloxane material, and wherein the envelope part comprises a glass.

The combination of light source and support is herein also indicated as assembly (see further below).

As indicated above, the lighting unit also comprises an envelope. The envelope is configured to provide a sealed space enclosing the light source and at least part of the support. Hence, the support may be entirely enclosed by the envelope, but may also partially be enclosed by the envelope. Especially, the entire laminate is enclosed by the envelope. The support may comprise different parts, including the laminate, and optionally also e.g. a gas stem (for providing gas to the enclosure formed by the envelope or remove gas therefrom).

The envelope comprises an envelope part transmissive for the lighting device light. This envelope part may also be indicated as light exit window. The envelope part may comprise a light transmissive material, such as a light transmissive polymeric material, like PMMA, or a ceramic material. Hence, the envelope part is especially a polymeric material. However, in another embodiment the envelope part (material) may comprise an inorganic material. Preferred inorganic materials are selected from the group consisting of glasses, (fused) quartz, transmissive ceramic materials, etc. Also hybrid materials, comprising both inorganic and organic parts may be applied, such as polysiloxanes. Especially preferred are PMMA, transparent PC, or glass as material for the window. Even more especially, the envelope part that is transmissive for the lighting device light comprises glass. In yet further specific embodiment, substantially the entire envelope may comprise light transmissive material, such as glass. Hence, in an embodiment the envelope essentially consists of glass. The envelope (part) is transmissive for lighting device light. In specific embodiments, however, (substantially) the (entire) envelope is substantially transparent for the lighting device light. In other embodiments, the envelope (part) is translucent (for the lighting device light). In embodiments, the entire envelope is transmissive for light.

The envelope provides (together with other elements such as in embodiments part of the support) a sealed space. Amongst others, the envelope may be sealed to part of the support with a seal, such as a cermet, an adhesive, a glue, a solder, etc. Especially, the sealed space comprises a filling gas comprising a thermally conductive gas, wherein the filling gas at least comprises oxygen (O₂). Without oxygen, the light source, especially the solid state light source, like especially the above mentioned solid state light source, has a lifetime shorter than desired. With too much oxygen, other issues may arise (see above). The filling gas especially comprises one or more of Ar, He, Ne, H₂, N₂, CO and CO₂. Optionally, the filling gas comprises air. Especially however, the filing gas at least comprises helium (He) or H₂, as these have the highest thermal conductivities. Even more especially, the filling as essentially comprises He and O₂. Especially, the filling gas further comprises He, and wherein the filling gas comprises 0.5-18 vol. %, even more especially 5-12 vol. %, yet even more especially not more than 10 vol. % oxygen (O₂). Especially, the filing gas essentially comprises He and O₂, and substantially no further components.

Due to the third layer, comprising an oxygen barrier material, the lifetime of the lighting unit is further increased. In embodiments, the oxygen barrier material comprises one or more of a metal, a metal oxide and a metal nitride. In yet further embodiments, the oxygen barrier material comprises copper. In other embodiments, the oxygen barrier material comprises one or more of alumina, silica, an aluminum nitride (AlNₓ) and a silicon nitride (SiNₓ). Especially, the third layer has no electrically conductive function and/or no thermally conductive function, though optionally one or more of these functions may also be used (if applicable).

In yet a further embodiment, the lighting unit may further comprise a control system configured to control the power provided to the one or more (solid state) light sources. Alternatively or additionally, the control system may be external from the lighting unit. Optionally, the control system may comprise a plurality of elements, of which some may be comprised by the lighting unit and others may be external from the lighting unit (such as a remote user interface, see also below). Optionally, also the power may be included in the lighting unit, such as in the case of certain handheld flash lights. The lighting unit may e.g. be integrated in a lighting system (comprising a plurality of lighting units) and optionally other type of lighting units than described herein. In yet a further specific embodiment, the control system is configured to control the power provided to the one or more (solid state) light sources as function of an input signal of a user interface. This user interface may be integrated in the lighting unit, but may also be remote from the lighting unit. Hence, the user interface may in embodiments be integrated in the lighting unit but may in other embodiments be separate from the lighting unit. The user interface may e.g. be a graphical user interface. Further, the user interface may be provided by an App for a Smartphone or other type of android device. Therefore, the invention also provides a computer program product, optionally implemented on a record carrier (storage medium), which when run on a computer executes the method as described herein (see below) and/or can control (the color temperature of the lighting unit light of) the lighting unit as described herein (as function of the power provided to the one or more (solid state) light sources). Alternatively or additionally, the control system is configured to control the power provided to the one or more (solid state) light sources as function of one or more of a sensor signal and a timer. To this end, e.g. a timer and/or a sensor may be used. For instance, the timer may be used to switch off after a predetermined time. Further, for instance the sensor may be a motion sensor, configured to sense motion, with the control system configured to switch on the lighting unit when the motion sensor senses motion or presence of e.g. a person. A control system or control unit may especially be of relevance when the lighting unit comprises a plurality of light sources.

The (functional) combination of light source (or lighting device) and support is herein also indicated as assembly. In yet a further aspect, the invention also provides such assembly of a light source and a support, wherein especially: (a) the light source is configured to provide light source light; and (b) the support is configured to support the light source; wherein the support comprises a laminate of layers, wherein the laminate of layers comprises an electrically conductive first layer, an electrically non-conducive second layer, and a third layer, wherein the first layer comprises copper, wherein the second layer comprises an epoxy-based material, and wherein the third layer comprises an oxygen barrier material.

It is further referred to the above (and below) described embodiments in relation to the light source, lighting device, support, support layers, etc.

In specific embodiments, the assembly comprises a lighting device, wherein the lighting device is configured to provide lighting device light; wherein the lighting device comprises said light source, wherein the lighting device further comprises a light converter configured to convert at least part of the light source light into light converter light, wherein the lighting device light comprises at least part of said light converter light and optionally part of said light source light, wherein the light source especially comprises a solid state light source, wherein the light source comprises a light emissive surface, wherein the light converter is, in specific embodiments, configured in physical contact with the light emissive surface; and wherein the assembly comprises a plurality of said light sources, wherein the support is configured to support said plurality of light sources. As indicated above, in embodiments the second layer comprises a stack of layers (with especially each layer being epoxy-based (and/or phenolic-based)).

Further, as indicated above, in specific embodiments the oxygen barrier material comprises one or more of copper, an alumina, a silica, an aluminum nitride and a silica nitride.

In yet a further aspect, the invention also provides a method for providing the assembly, such as defined herein, wherein the method comprises: (a) providing a support, wherein the support comprises a laminate of layers, wherein the laminate of layers comprises an electrically conductive first layer, an electrically non-conducive second layer, and a third layer, wherein the first layer comprises copper, wherein the second layer comprises an epoxy-based material (and/or phenolic-based material), and wherein the third layer comprises an oxygen barrier material; and (b) functionally connecting a light source to the support, functionally connecting a plurality of said light sources to the support.

The light source is especially functionally coupled to the first layer. The first layer may include tracks of electrically conductive material. Alternatively, the first layer may comprise cavities of electrically non-conductive material. For instance, with etching the first layer may be structures such that the electrically conductive material provides electrically conductive tracks for powering the light source. The light source is thus especially functionally coupled with such electrically conductive tracks which are comprised by the first layer.

The support with the laminate may be provided as such. Hence, the invention also provides the assembly obtainable by the herein described method for providing the assembly.

In yet other embodiments, also a laminate without the third layer, i.e. a support precursor, may be provided. In such embodiments the method may also include providing the third layer to the laminate (or here support precursor). Hence, in embodiments the method may comprise: (i) providing a support precursor, wherein the support precursor comprises a laminate of layers, wherein the laminate of layers comprises an electrically conductive first layer, and an electrically non-conductive second layer; wherein the first layer especially comprises copper, and wherein the second layer especially comprises an epoxy-based material (and/or phenolic-based material); and (ii) providing in a processing stage the third layer to the second layer, wherein the third layer comprises an oxygen barrier material, to provide said support, wherein the processing stage in specific embodiments comprises one or more of (a) using the second layer as adhesive layer for the third layer, (b) sputtering a third layer precursor to the second layer to provide said third layer (by conversion of the third layer precursor into the third layer), and (c) ALD coating a third layer precursor to the second layer to provide said third layer (by conversion of the third layer precursor into the third layer). Hereby, the assembly is provided. Atomic layer deposition (ALD) and sputtering are method known in the art.

The support may comprise a support edge, especially at least two support edges, such as four support edges. Optionally, these edges may be provided with a coating layer comprising an oxygen barrier material (not necessarily the same as comprised by the third layer). Hence, in embodiments the support comprises a support edge, wherein the method further comprises coating the support edge with a coating layer comprising an oxygen barrier material. Especially, the oxygen barrier material (of the coating layer) comprises one or more of copper, an alumina, a silica, an aluminum nitride and a silica nitride. Especially, with such coated edge the filling gas may comprises 0.5-10 vol. %, even more especially 0.5-5 vol. %, yet even more especially not more than 2 vol. % oxygen (O₂). Further, as indicated above, the filling gas may especially comprise He.

Further, the support may substantially have a flat cross-sectional plane (in the plane of the support (in the plane of the laminate layers). Especially however, the support may be bended or facetted. This may allow generation of the light source light in a plurality of (opposite directions). Hence, the method may also comprise shaping the support into a facetted or bended support. For instance, the facetted or bended support may have a cross-sectional plane (perpendicular to the plane parallel to the laminate) having a shape selected from a circle, an ellipse, a (equilateral) triangle, a square, a rectangle, a regular pentagon, a regular hexagon, a regular heptagon, a regular octagon, or other polygon with three or more sides.

In yet a further aspect, the invention also provides a method for producing the lighting unit as especially described herein. Hence, the invention provides a method for producing the lighting unit, especially described herein, wherein the method comprises: (a) providing a lighting device configured to provide lighting device light; wherein the lighting device comprises a light source; (b) providing a support; wherein the support comprises a laminate of layers, wherein the laminate of layers comprises an electrically conductive first layer, an electrically non-conducive second layer, and a third layer, wherein the first layer especially comprises copper, wherein the second layer especially comprises an epoxy-based material (and/or phenolic-based material), and wherein the third layer especially comprises an oxygen barrier material; (c) providing an envelope comprising an envelope part transmissive for the lighting device light; (d) providing a filling gas comprising a thermally conductive gas, wherein the filling gas at least comprises oxygen (O₂); and (e) functionally connecting a light source to the support, enclosing the light source and at least part of the support with the envelope to provide a sealed space enclosing the light source and at least part of the support, wherein the sealed space comprise said filling gas. Hence, the invention also provides the lighting unit obtainable by the herein described method for providing the lighting unit.

The lighting device may be part of or may be applied in e.g. office lighting systems, household application systems, shop lighting systems, home lighting systems, accent lighting systems, spot lighting systems, theater lighting systems, fiber-optics application systems, projection systems, self-lit display systems, pixelated display systems, segmented display systems, warning sign systems, medical lighting application systems, indicator sign systems, decorative lighting systems, portable systems, automotive applications, green house lighting systems, horticulture lighting, or LCD backlighting.

As indicated above, the lighting unit may be used as backlighting unit in an LCD display device. Hence, the invention provides also a LCD display device comprising the lighting unit as defined herein, configured as backlighting unit. The invention also provides in a further aspect a liquid crystal display device comprising a back lighting unit, wherein the back lighting unit comprises one or more lighting devices as defined herein.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIGS. 1a-1b schematically depict designs of a low cost LED bulb/lighting unit using a conventional glass bulb that can be filled with He and O₂;

FIGS. 2a-2d schematically depicts some aspects in relation to the support;

FIG. 3 depicts the lifetimes (khr.) as a function of O₂ concentrations (in vol. % of the total gas content) for a He:O₂ filled 60 W LED bulb, for a PCB based on single sided copper (red squares) and double sided copper (blue diamonds); and

FIGS. 4a-4f schematically depict some further aspects.

The schematic drawings are not necessarily on scale.

### DETAILED DESCRIPTION OF THE EMBODIMENTS

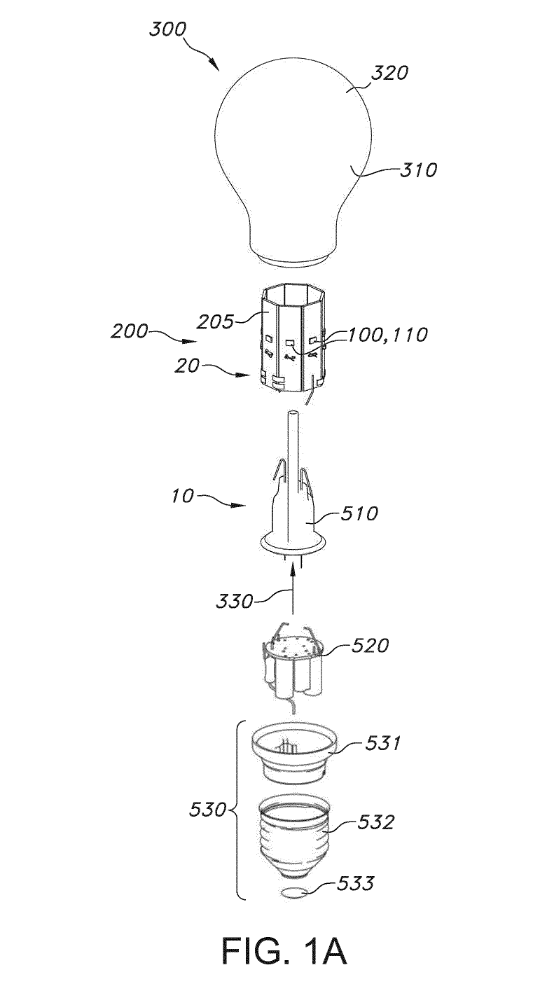

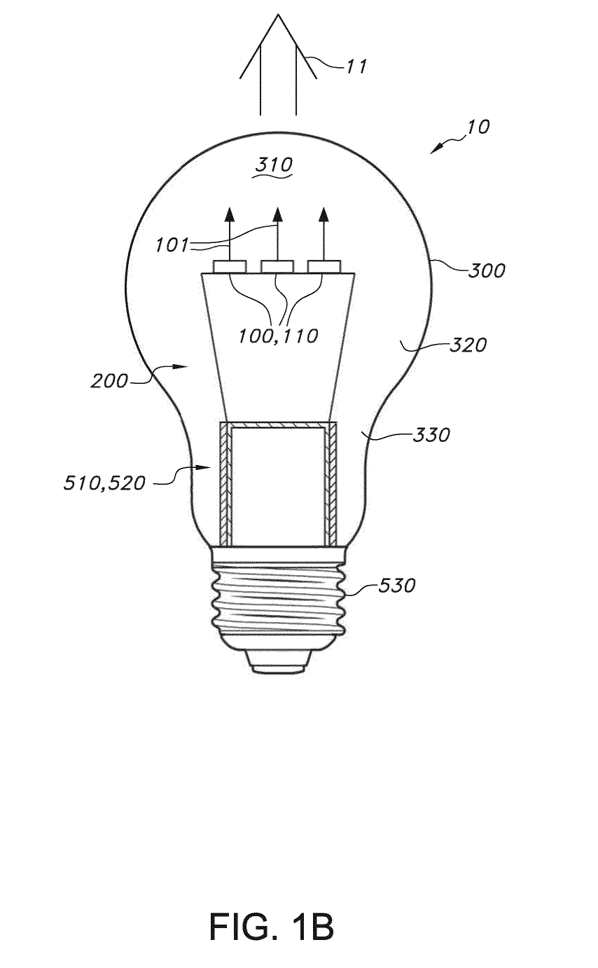

FIGS. 1a-1b schematically depict designs of a low cost LED bulb/lighting unit using a conventional glass bulb that can be filled with He and O₂.

FIG. 1a schematically depicts an embodiment how the lighting unit may be assembled, hereby assuming that the assembly, indicated with reference 20, is available. FIG. 1a schematically depicts the assembly of the lighting unit 10 comprising a lighting device 100, a support 200, and an envelope 300. The lighting device 100 is configured to provide lighting device light (not depicted). The lighting device 100 comprises a light source 110. The support 200 is configured to support the light source 110. The support 200 with functionally coupled light source 110 is herein also indicated as assembly 20. The envelope 300 provides a sealed space 310 enclosing the light source 110 and at least part of the support 200. The envelope 300 comprises an envelope part 320 transmissive for the lighting device light 101. For instance, the envelope 300 is a glass envelope. The sealed space 310 comprises a filling gas 330 (see FIG. 1b) comprising a thermally conductive gas; in FIG. 1a, reference 330 and the arrow indicate that the filling gas is introduce into the envelope 300 during assembly, or after a substantial part of the assembly but before closure of a gas stem (see element 510). Especially, the filling gas 330 at least comprises oxygen O₂. Reference 510 indicates an element including such gas stem and wiring. The gas stem is used during assembly for controlling the gas atmosphere in the envelope. After creating substantially the right gas atmosphere, especially oxygen and helium, the stem is closed, such as by melting or sealing. In this way, the sealed space 310 is provided.

The O₂ concentration impacts the thermal conductivity of the gas mixture. At 20% O₂ the thermal conductivity of a He:O₂ mixture is about 130 mW/m-K, for a 90:10 He:O₂ mixture it is 143 mW/m-K, and for a 95:5 He:O₂ mixture it is 150 mW/m-K at STP (standard temperature and pressure). Hence lowering the O₂ content improves the thermal conductivity and hence reduces the thermal resistance of the LED lamp. A lower thermal resistance then enables higher lamp efficiencies and hence a cost reduction, e.g. through using a lower LED count. A reduction from 20% to 10% or from 10% would 5% oxygen by volume of the total gas in the enclosure would imply a significant cost reduction. However, with the present standard support materials used, the O₂ content is depleted too quickly, thereby not allowing lower O₂ contents.

Reference 520 indicates an element comprising electronics, such as a driver. Reference 530 indicates the cap, which may e.g. include a plastic ring, indicated with reference 531, e.g. an E27 cap (side contact), indicated with reference 532 and a solder (center contact), and indicated with reference 533. The contacts are configured for electrical contact for powering of the lighting unit.

FIG. 1b schematically depicts another embodiment of the lighting unit. Here, a differently shaped support 200 has been applied.

The lighting devices 100 are configured to provide lighting device light 101 (see FIG. 1b). This light will at least partly be transmitted through the transmissive envelope part 320 (here in fact the entire envelope 300 may be transmissive, as e.g. a glass envelope may be applied) to provide lighting unit light 11. This may especially be white light.

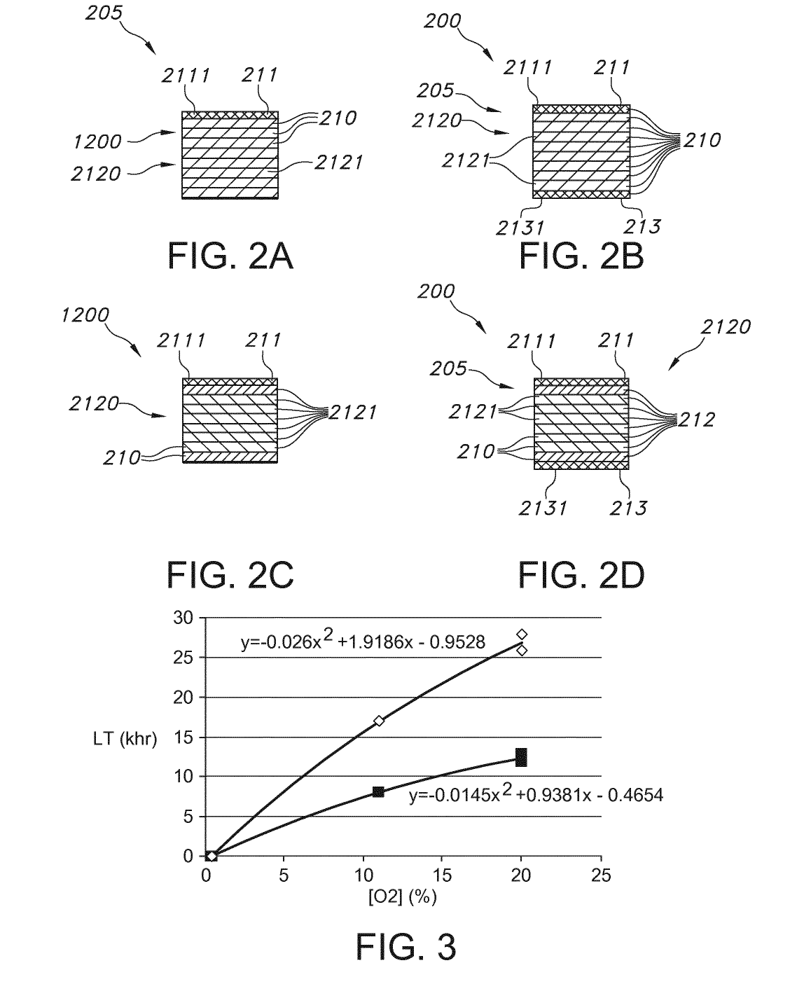

FIG. 2a-2d schematically depict composite cross-sections showing the structure of (a) a first embodiment as single-sided copper clad laminate; (b) a second embodiment, the same as in FIG. 2a, but now as double-sided copper clad laminate; (c) a third embodiment, differing from the first embodiment of FIG. 2a as single-sided copper clad laminate; and (d) a fourth embodiment, the same as in FIG. 2c, but now as double-sided copper clad laminate. In the drawings layers 211 and 213 indicate copper layers, layers 212 indicated woven layers of epoxy-impregnated woven glass (glass cloth), whereas the additional dotted layers indicate epoxy-impregnated layers containing random glass material (glass mat). For instance, referring to FIGS. 2c and 2d, the top layer and the bottom layer of the second layer laminate 2120 may sandwich layers that comprise one or more woven layers of epoxy-impregnated woven glass (glass cloth). The copper foils are in all cases directly attached to the impregnated layer by the epoxy resin. The amount of layers depends on the desired thickness. The support 200 (FIGS. 2b/2d) comprises a laminate 205 of layers 210. The laminate 205 of layers 210 comprises an electrically conductive first layer 211, an electrically non-conducive second layer 212, and a third layer 213. The first layer 211 comprises e.g. copper 2111; the second layer 212 comprises e.g. an epoxy-based material 2121; and the third layer 213 comprises an oxygen barrier material 2131, here e.g. also a copper layer by way of example. Note that the second layer 212 comprises a stack or laminate of layers 2120. The second layer 212 may comprise more or less layers than schematically depicted in FIGS. 2a-2d. As FIGS. 2a and 2c do not (yet) show the third layer 213, these laminates or stacks are also indicated as support precursor 1200.

The inventors have observed that during operation the O2 content is reduced in an LED bulb filled with O2 and helium. They have found that when standard single-sided “copper clad laminates” (CCL), e.g. those with epoxy-glass composite materials, are used, O2 consumption under operating conditions is dominated by the support material (epoxy). The LED packages, solder flux and solder mask surprisingly appear to contribute to the overall O₂ consumption rate to a significantly lower level. They also found that the O₂ consumption rate of PCB support samples (partially) shielded from O₂ through adhesion to a (35 μm) thick copper layer is strongly reduced compared to samples that are not or less covered by such a copper layer. The O₂ consumption rate was tested for 250 hours at 120° C. for supports without oxygen barrier and covered with copper on one side (SSC) and supports without oxygen barrier (supports including copper on two sides (DSC)). It appears that copper in the latter examples acts as a barrier layer preventing (strongly delaying) the thermal oxidation of the epoxy.

Using a so-called “double sided copper” (DSC) instead of standard “single sided copper” (SSC) CCL strongly reduces the oxidation rate of the organic CCL material (epoxy), enabling longer lifetimes, allowing a lower O₂ content, and thereby improving Rth significantly.

An embodiment is given in FIG. 3. For a 60 W equivalent LED lamp with a light engine consisting of a SSC CCL, 14.4% O₂ by volume of the total gas content is needed to reach a lifetime of 10 khr. (10,000 h) at 25° C. ambient. For a light engine composed of a DSC CCL only 6.4% O₂ is needed to meet the same requirement, as a consequence of the much lower O₂ consumption rate. The LED temperatures (Tj, Ts) of the DSC will be about 3° C. lower when the lamp is operated at the same forward current, which is beneficial for the lumen maintenance and the LED efficiency. The thermal resistance from the solder point to ambient (Rth(sp-amb)) is about 2 K/W lower, from 17 K/W for a lamp filled with 14.4% O₂ to 15 K/W for a lamp filled with 6.4% O₂. This enables significant cost reduction because it allows a higher current per LED and hence a reduced LED count for the same light output. When the edges of the support would be coated, the oxygen content could be even lower.

Alternatively, other materials may be used as a barrier layer to delay/prevent thermal oxidation of the epoxy, such as: other metals (e.g. aluminum), metal oxides (e.g. SiO₂, Al₂O₃), metal nitrides (e.g. SiNₓ), etc. The electrically non-functional metal layer at the rear need not be 35 μm, but just needs to be thick enough to prevent oxygen diffusion into the epoxy layer. The barrier layer may be applied in many different forms. In this example adhesion using the epoxy material is used, but alternatively sputtering may be used, or evaporation, ALD coating etc., as long as the barrier provides a (moderate) barrier to oxygen gas.

Alternatively, also the sides of the PCB may be covered with a barrier layer, (see also below).

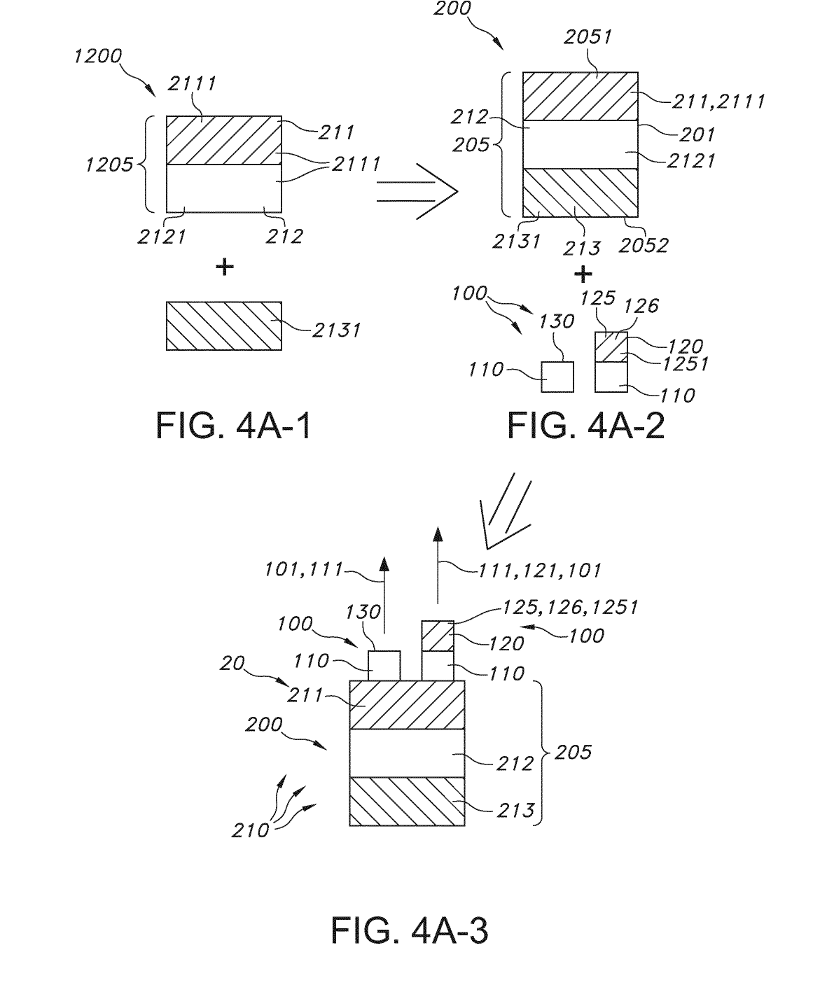

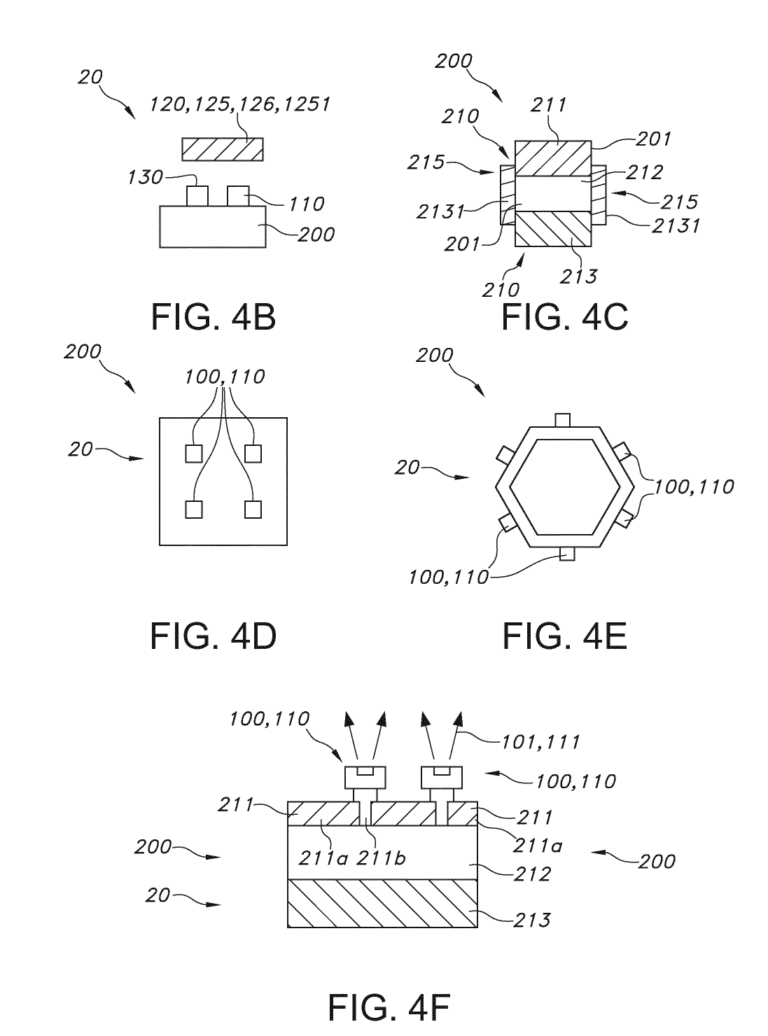

FIG. 4a very schematically depicts an embodiment how a support 200 and assembly 20 may be made. First (FIG. 4a-1), a support precursor 1200 is provided. The support precursor 1200 comprises a laminate 1205 of layers 1210. The laminate 1205 of layers 1210 comprises an electrically conductive first layer 211, and an electrically non-conducive second layer 212. As indicated above, the first layer 211 may especially comprise copper 2111 and the second layer 212 may especially comprises an epoxy-based material 2121, such as a woven cloth of glass fibers with epoxy resin. Of course, one may also provide the support 200 from scratch, starting with one of these layers and providing the other layer thereto.

Note that the term “layer” may also refer to a plurality of stacked layers. For instance, the second layer may comprise a laminate of layers. Alternatively or additionally, the first layer may comprise a laminate of layers. Alternatively or additionally, the third layer may comprise a laminate of layers. Further, especially with reference to the first layer, this layer may include tracks of electrically conductive material, especially thus copper, and parts between the tracks with electrically non-conductive material or no material at all, for electrical isolation between the tracks. Only for the sake of drawing, the first layer is schematically shown as an integral layer; see however also FIG. 4f).

Subsequently, in a processing stage the third layer 213 is provided to the second layer 212 (FIG. 4a-2). The third layer 213 comprises an oxygen barrier material 2131. In this way the support 200 is provided. For instance, the processing stage may comprises one or more of a using the second layer 212 as adhesive layer for the third layer 213, sputtering a third layer precursor to the second layer 212 to provide said third layer 213, and ALD coating a third layer precursor to the second layer 212 to provide said third layer 213.

Subsequently, one or more light sources 110 are functionally connected a to the support 200 (FIG. 4a-3). In this way an assembly 20 is obtained.

Here, by way of example a lighting device 100 essentially comprising a light source 110 (left) and a lighting device 100 comprising a light source 110 and a converter 120 (right) are depicted. Hence, the lighting device 100 as schematically depicted on the right of the assembly 20 further comprises a light converter 120 configured to convert at least part of the light source light 111 into light converter light 121. In this way, the lighting device light 101 comprises at least part of said light converter light 121 and optionally part of said light source light 111. Especially, the light converter 120 comprises a polymeric material 125 and a luminescent material 126, wherein the polymeric material 125 comprises a polysiloxane material 1251. The laminate 205 has two laminate faces 2051 and 2052, defining the laminate height. Other faces may be considered edges of the laminate. The edges are indicated with reference 201. The laminate 205 height may e.g. be in the order of 20-50 mm, such as 25-40 mm.

FIG. 4b very schematically depicts an embodiment wherein the light converter 120 is configured at a distance of the light emissive surface 130 of the light source(s) 110. Further, by way of example here an embodiment is depicted were more than one light source 110 are radiationally coupled to a single light converter 120. Of course, other embodiments may also be possible, such as each light source its own light converter, in physical contact with the light emissive surface 130 or not.

The support 200 comprises a support edge 201. The term “edge” may also refer to a plurality of edges. At least part of the edge 201 may include a coating layer 215 comprising an oxygen barrier material 2131, which may be same as comprised by the third layer or which may also be different, see also FIG. 4c. Hence, the method as described herein may further comprise coating the support edge 201 with a coating layer 215 comprising an oxygen barrier material 2131. Also this the oxygen barrier material 2131 may especially comprise one or more of copper, an alumina, a silica, an aluminum nitride and a silica nitride. The coating layer 215 may in embodiments comprise a laminate of layers.

FIG. 4d schematically depict an embodiment of the support 200 or assembly 20, i.e. the support 200 including one or more light sources 110, in top view. If desired, the support can be flat, as schematically depicted here, but the support may also be provided as bended or curved material, before, during or after application of the light sources 110 and/or the third layer, but especially after application of the light sources 110 and/or the third layer 213. A folded support is schematically depicted in FIG. 4e. Hence, the method as described herein may further comprise shaping the support 200 into a facetted or bended support 200. Especially, such method will be applied when the support is provided with a plurality of the light sources 110. In FIG. 4e, the facetted support 200 has a cross-sectional plane (perpendicular to the plane parallel to the laminate) have regular hexagon shape.

FIG. 4f schematically depicts the light source 110 being functionally coupled to the first layer 211. The first layer 211 include tracks 211a of electrically conductive material and tracks or cavities, indicated with reference 211b of electrically non-conductive material, including gas (no solid material at all). For instance, by etching the first layer 211 structures may be formed such that the electrically conductive material provides electrically conductive tracks for powering the light source 110. The light source is thus especially functionally coupled with such electrically conductive tracks 211a which are comprised by the first layer. For instance, conductors of the light source may be soldered to the tracks. This is known to the person skilled in the art.

The term “substantially” herein, such as in “substantially all light” or in “substantially consists”, will be understood by the person skilled in the art. The term “substantially” may also include embodiments with “entirely”, “completely”, “all”, etc. Hence, in embodiments the adjective substantially may also be removed. Where applicable, the term “substantially” may also relate to 90% or higher, such as 95% or higher, especially 99% or higher, even more especially 99.5% or higher, including 100%. The term “comprise” includes also embodiments wherein the term “comprises” means “consists of”. The term “and/or” especially relates to one or more of the items mentioned before and after “and/or”. For instance, a phrase “item 1 and/or item 2” and similar phrases may relate to one or more of item 1 and item 2. The term “comprising” may in an embodiment refer to “consisting of” but may in another embodiment also refer to “containing at least the defined species and optionally one or more other species”.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

The devices herein are amongst others described during operation. As will be clear to the person skilled in the art, the invention is not limited to methods of operation or devices in operation.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. Use of the verb “to comprise” and its conjugations does not exclude the presence of elements or steps other than those stated in a claim. The article “a” or “an” preceding an element does not exclude the presence of a plurality of such elements. The invention may be implemented by means of hardware comprising several distinct elements, and by means of a suitably programmed computer. In the device claim enumerating several means, several of these means may be embodied by one and the same item of hardware. The mere fact that certain measures are recited in mutually different dependent claims does not indicate that a combination of these measures cannot be used to advantage.

The invention further applies to a device comprising one or more of the characterizing features described in the description and/or shown in the attached drawings. The invention further pertains to a method or process comprising one or more of the characterizing features described in the description and/or shown in the attached drawings.

The various aspects discussed in this patent can be combined in order to provide additional advantages. Further, the person skilled in the art will understand that embodiments can be combined, and that also more than two embodiments can be combined. Furthermore, some of the features can form the basis for one or more divisional applications.

1. A lighting unit comprising a lighting device, a support, and an envelope, wherein:
the lighting device is configured to provide lighting device light; wherein the lighting device comprises a light source;
the support is configured to support the light source; wherein the support comprises a laminate of layers, wherein the laminate of layers comprises an electrically conductive first layer, an electrically non-conducive second layer, and a third layer, wherein the first layer comprises copper, wherein the second layer comprises an epoxy-based material, and wherein the third layer comprises an oxygen barrier material;
the envelope is configured to provide a sealed space enclosing the light source and at least part of the support; wherein the envelope comprises an envelope part transmissive for the lighting device light, and wherein the sealed space comprise a filling gas comprising a thermally conductive gas, wherein the filling gas at least comprises oxygen;
wherein the third layer prevents oxygen from migrating from the envelope to the second layer and oxidizing the epoxy-based material.

2. The lighting unit according to claim 1, wherein the light source is configured to provide light source light, wherein the lighting device further comprises a light converter configured to convert at least part of the light source light into light converter light, wherein the lighting device light comprises at least part of said light converter light and optionally part of said light source light, wherein the light converter comprises a polymeric material and a luminescent material, wherein the polymeric material comprises a polysiloxane material, and wherein the envelope part comprises a glass.

3. The lighting unit according to claim 2, wherein light source comprises a solid state light source, wherein the light source comprises a light emissive surface, and wherein the light converter is configured in physical contact with the light emissive surface.

4. The lighting unit according to claim 1, wherein the oxygen barrier material comprises copper.

5. The lighting unit according to claim 1, wherein the oxygen barrier material comprises one or more of alumina, silica, an aluminum nitride and a silica nitride.

6. The lighting unit according to claim 1, wherein the second layer comprises a stack of layers.

7. The lighting unit according to claim 1, wherein the filling gas further comprises He, and wherein the filling gas comprises 0.5-12 vol. % oxygen.

8. The lighting unit according to claim 1, wherein the lighting unit comprises a plurality of light sources, and wherein the support is configured to support said plurality of light sources.

9. An assembly of a light source and a support, wherein:
the light source is configured to provide light source light; and
the support is configured to support the light source; wherein the support comprises a laminate of layers, wherein the laminate of layers comprises an electrically conductive first layer, an electrically non-conducive second layer, and a third layer, wherein the first layer comprises copper, wherein the second layer comprises an epoxy-based material, and wherein the third layer comprises an oxygen barrier material;
wherein the third layer prevents oxygen from migrating to the second layer and oxidizing the epoxy-based material.

10. The assembly according to claim 9, comprising a lighting device, wherein:
the lighting device is configured to provide lighting device light; wherein the lighting device comprises said light source, wherein the lighting device further comprises a light converter configured to convert at least part of the light source light into light converter light, wherein the lighting device light comprises at least part of said light converter light and optionally part of said light source light, wherein the light source comprises a solid state light source, wherein the light source comprises a light emissive surface, wherein the light converter is configured in physical contact with the light emissive surface; and
the assembly comprises a plurality of said light sources, wherein the support is configured to support said plurality of light sources, and wherein the second layer comprises a stack of layers.

11. The assembly according to claim 9, wherein the oxygen barrier material comprises one or more of copper, alumina, silica, an aluminum nitride, and a silicon nitride.

12. A method for providing the assembly according to claim 9, the method comprising:
providing a support, wherein the support comprises a laminate of layers, wherein the laminate of layers comprises an electrically conductive first layer, an electrically non-conducive second layer, and a third layer, wherein the first layer comprises copper, wherein the second layer comprises an epoxy-based material, and wherein the third layer comprises an oxygen barrier material; wherein the third layer prevents oxygen from migrating from the envelope to the second layer and oxidizing the epoxy-based material, and
functionally connecting a light source to the support.

13. The method according to claim 12, the method comprising:
providing a support precursor, wherein the support precursor comprises a laminate of layers, wherein the laminate of layers comprises an electrically conductive first layer, and an electrically non-conducive second layer; wherein the first layer comprises copper, and wherein the second layer comprises an epoxy-based material; and
providing in a processing stage the third layer to the second layer, wherein the third layer comprises an oxygen barrier material, to provide said support, wherein the processing stage comprises one or more of using the second layer as adhesive layer for the third layer, sputtering a third layer precursor to the second layer to provide said third layer, and ALD coating a third layer precursor to the second layer to provide said third layer.

14. The method according to claim 12, wherein the support comprises a support edge, wherein the method further comprises coating the support edge with a coating layer comprising an oxygen barrier material.

15. A method for producing the lighting unit according to claim 1, wherein the method comprises:
providing a lighting device configured to provide lighting device light; wherein the lighting device comprises a light source;
providing a support; wherein the support comprises a laminate of layers, wherein the laminate of layers comprises an electrically conductive first layer, an electrically non-conducive second layer, and a third layer, wherein the first layer comprises copper, wherein the second layer comprises an epoxy-based material, and wherein the third layer comprises an oxygen barrier material;
providing an envelope comprising an envelope part transmissive for the lighting device light;
providing a filling gas comprising a thermally conductive gas, wherein the filling gas;
functionally connecting a light source to the support, enclosing the light source and at least part of the support with the envelope to provide a sealed space enclosing the light source and at least part of the support, wherein the sealed space comprise said filling gas;
wherein the third layer prevents oxygen from migrating from the envelope to the second layer and oxidizing the epoxy-based material.
